(19) United States
(12) Patent Application Publication
(10) Pub. No.: US 2024/0090203 A1
(43) Pub. Date: Mar. 14, 2024

(54) SEMICONDUCTOR STORAGE DEVICE

(71) Applicant: Kioxia Corporation, Tokyo (JP)

(72) Inventors: Takanori AKITA, Yokkaichi Mie (JP); Kotaro NODA, Yokkaichi Mie (JP); Seiichi URAKAWA, Yokkaichi Mie (JP); Mutsumi OKAJIMA, Yokkaichi Mie (JP)

(73) Assignee: Kioxia Corporation, Tokyo (JP)

(21) Appl. No.: 18/455,732

(22) Filed: Aug. 25, 2023

(30) Foreign Application Priority Data
Aug. 26, 2022 (JP) 2022-134851

(51) Int. Cl. H10B 12/00

(52) U.S. Cl. CPC H10B 12/482; H10B 12/02; H10B 12/33

(57) ABSTRACT

A semiconductor storage device includes a first oxide semiconductor layer that extends in a first direction; a second oxide semiconductor layer that extends in the first direction and is adjacent to the first oxide semiconductor layer in a second direction intersecting to the first direction; first wiring that extends in a third direction intersecting to the first direction and overlaps with the first oxide semiconductor layer in the third direction; second wiring that extends in the third direction and overlaps with the second oxide semiconductor layer in the third direction; a first insulating film that is provided between the first wiring and the first oxide semiconductor layer; a second insulating film that is provided between the second wiring and the second oxide semiconductor layer; a first conductor that is provided on the first oxide semiconductor layer; a second conductor that is provided on the second oxide semiconductor layer; and an insulating layer that has a gap between the first conductor and the second conductor or between the first wiring and the second wiring.

### CROSS-REFERENCE TO RELATED APPLICATION

This application is based upon and claims the benefit of priority from Japanese Patent Application No. 2022-134851, filed Aug. 26, 2022, the entire contents of which are incorporated herein by reference.

### FIELD

Embodiments described herein relate generally to a semiconductor storage device.

### BACKGROUND

A semiconductor storage device including bit lines, word lines, and memory cell connected thereto (transistors and capacitors) is used. Data can be written to and read from memory cells by selecting bit lines and word lines and applying voltages thereto.

### DESCRIPTION OF THE DRAWINGS

FIG. 1 is a circuit diagram illustrating a circuit configuration example of a memory cell array.

FIG. 2 is a schematic cross-sectional view illustrating a structure example of a semiconductor storage device.

FIG. 3 is a schematic plan view illustrating a structure example of the memory cell array.

FIG. 4 is a schematic cross-sectional view illustrating the structure example of the memory cell array.

FIG. 5 is a schematic cross-sectional view illustrating the structure example of the memory cell array.

FIG. 6 is a schematic cross-sectional view illustrating a first structure example of the memory cell array.

FIG. 7 is a schematic cross-sectional view illustrating the first structure example of the memory cell array.

FIG. 8 is a schematic cross-sectional view illustrating a first manufacturing method example in the first structure example.

FIG. 9 is a schematic cross-sectional view illustrating the first manufacturing method example of the first structure example.

FIG. 10 is a schematic cross-sectional view illustrating the first manufacturing method example of the first structure example.

FIG. 11 is a schematic cross-sectional view illustrating the first manufacturing method example of the first structure example.

FIG. 12 is a schematic cross-sectional view illustrating the first manufacturing method example of the first structure example.

FIG. 13 is a schematic cross-sectional view illustrating the first manufacturing method example of the first structure example.

FIG. 14 is a schematic cross-sectional view illustrating the first manufacturing method example of the first structure example.

FIG. 15 is a schematic cross-sectional view illustrating the first manufacturing method example of the first structure example.

FIG. 16 is a schematic cross-sectional view illustrating the first manufacturing method example of the first structure example.

FIG. 17 is a schematic cross-sectional view illustrating the first manufacturing method example of the first structure example.

FIG. 18 is a schematic cross-sectional view illustrating the first manufacturing method example of the first structure example.

FIG. 19 is a schematic cross-sectional view illustrating the first manufacturing method example of the first structure example.

FIG. 20 is a schematic cross-sectional view illustrating the first manufacturing method example of the first structure example.

FIG. 21 is a schematic cross-sectional view illustrating the first manufacturing method example of the first structure example.

FIG. 22 is a schematic cross-sectional view illustrating the first manufacturing method example of the first structure example.

FIG. 23 is a schematic cross-sectional view illustrating the first manufacturing method example of the first structure example.

FIG. 24 is a schematic cross-sectional view illustrating the first manufacturing method example of the first structure example.

FIG. 25 is a schematic cross-sectional view illustrating the first manufacturing method example of the first structure example.

FIG. 26 is a schematic cross-sectional view illustrating the first manufacturing method example of the first structure example.

FIG. 27 is a schematic cross-sectional view illustrating the first manufacturing method example of the first structure example.

FIG. 28 is a schematic cross-sectional view illustrating a second manufacturing method example of the first structure example.

FIG. 29 is a schematic cross-sectional view illustrating the second manufacturing method example of the first structure example.

FIG. 30 is a schematic cross-sectional view illustrating the second manufacturing method example of the first structure example.

FIG. 31 is a schematic cross-sectional view illustrating the second manufacturing method example of the first structure example.

FIG. 32 is a schematic cross-sectional view illustrating the second manufacturing method example of the first structure example.

FIG. 33 is a schematic cross-sectional view illustrating the second manufacturing method example of the first structure example.

FIG. 34 is a schematic cross-sectional view illustrating a first modification example of the first structure example of the memory cell array.

FIG. 35 is a schematic cross-sectional view illustrating the first modification example of the first structure example of the memory cell array.

FIG. 36 is a schematic cross-sectional view illustrating a second modification example of the first structure example of the memory cell array.

FIG. 37 is a schematic cross-sectional view illustrating the second modification example of the first structure example of the memory cell array.

FIG. 38 is a schematic plan view illustrating a second structure example of the memory cell array.

FIG. 39 is a schematic plan view illustrating the second structure example of the memory cell array.

FIG. 40 is a schematic cross-sectional view illustrating a manufacturing method example of the second structure example.

FIG. 41 is a schematic cross-sectional view illustrating the manufacturing method example of the second structure example.

FIG. 42 is a schematic cross-sectional view illustrating the manufacturing method example of the second structure example.

FIG. 43 is a schematic cross-sectional view illustrating the manufacturing method example of the second structure example.

FIG. 44 is a schematic cross-sectional view illustrating the second manufacturing method example of the first structure example.

FIG. 45 is a schematic cross-sectional view illustrating the second manufacturing method example of the first structure example.

FIG. 46 is a schematic plan view illustrating the first modification example of the second structure example.

FIG. 47 is a schematic cross-sectional view illustrating the first modification example of the second structure example.

FIG. 48 is a schematic plan view illustrating the second modification example of the second structure example of the memory cell array.

FIG. 49 is a schematic plan view illustrating the second modification example of the second structure example of the memory cell array.

FIG. 50 is a schematic plan view illustrating a third modification example of the second structure example of the memory cell array.

FIG. 51 is a schematic plan view illustrating the third modification example of the second structure example of the memory cell array.

FIG. 52 is a schematic plan view illustrating the third modification example of the second structure example of the memory cell array.

FIG. 53 is a schematic plan view illustrating the third modification example of the second structure example of the memory cell array.

FIG. 54 is a schematic plan view illustrating the third modification example of the second structure example of the memory cell array.

FIG. 55 is a schematic plan view illustrating the third modification example of the second structure example of the memory cell array.

FIG. 56 is a schematic plan view illustrating the third modification example of the second structure example of the memory cell array.

FIG. 57 is a schematic plan view illustrating the third modification example of the second structure example of the memory cell array.

### DETAILED DESCRIPTION

Embodiments provide prevention of deterioration of reliability of a semiconductor storage device.

In general, according to at least one embodiment, a semiconductor storage device includes a first oxide semiconductor layer that extends in a first direction; a second oxide semiconductor layer that extends in the first direction and is adjacent to the first oxide semiconductor layer in a second direction intersecting to the first direction; first wiring that extends in a third direction intersecting to the first direction and overlaps with the first oxide semiconductor layer in the third direction; second wiring that extends in the third direction and overlaps with the second oxide semiconductor layer in the third direction; a first insulating film that is provided between the first wiring and the first oxide semiconductor layer; a second insulating film that is provided between the second wiring and the second oxide semiconductor layer; a first conductor that is provided on the first oxide semiconductor layer; a second conductor that is provided on the second oxide semiconductor layer; and an insulating layer that has a gap between the first conductor and the second conductor or between the first wiring and the second wiring.

Hereinafter, embodiments are described with reference to the drawings. The relationship between the thickness and plane dimension of each component illustrated in the drawings, the ratio of the thickness of each component, and the like may differ from the actual product. The vertical direction may differ from the vertical direction according to gravitational acceleration. Further, in the embodiments, substantially the same elements are denoted by the same reference numerals, and description thereof is omitted as appropriate.

In the present specification, “connection” includes not only physical connection but also electrical connection and includes not only direct connection but also indirect connection unless otherwise specified.

A semiconductor memory device according to an embodiment is a dynamic random access memory (DRAM) and has a memory cell array.

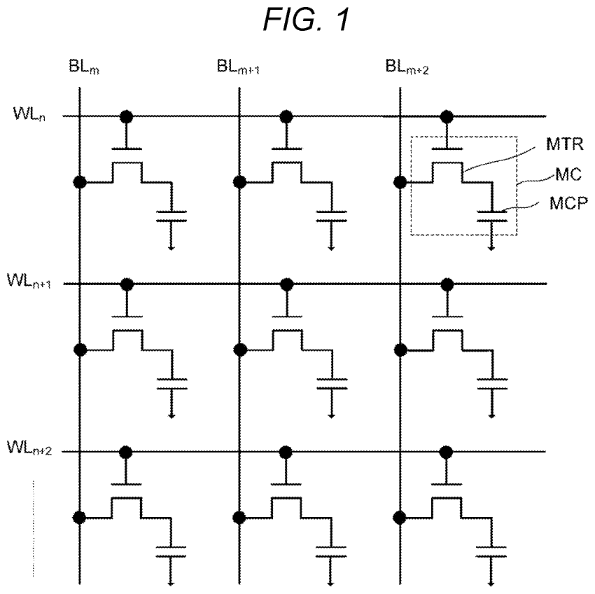

FIG. 1 is a circuit diagram illustrating a circuit configuration example of a memory cell array. FIG. 1 illustrates a plurality of memory cells MC, a plurality of word lines WL (a word line WLₙ, a word line WLₙ₊₁, and a word line WLₙ₊₂, n is an integer), and a plurality of bit lines BL (a bit line BLₘ, a bit line BLₘ₊₁, and a bit line BLₘ₊₂, m is an integer).

The plurality of memory cells MC are located in a matrix direction and form a memory cell array. The memory cells MC each include a memory transistor MTR that is a field effect transistor (FET) and a memory capacitor MCP. A gate of the memory transistor MTR is connected to the corresponding word line WL, and one of a source or a drain is connected to the corresponding bit line BL. One electrode of the memory capacitor MCP is connected to the other one of the source or the drain of the memory transistor MTR, and the other electrode is connected to a power supply line (not illustrated) that supplies a specific voltage. The memory cell MC can store data by accumulating charges from the bit line BL to the memory capacitor MCP by switching the memory transistor MTR by the word line WL. The number of the plurality of memory cells MC is not limited to the number illustrated in FIG. 1.

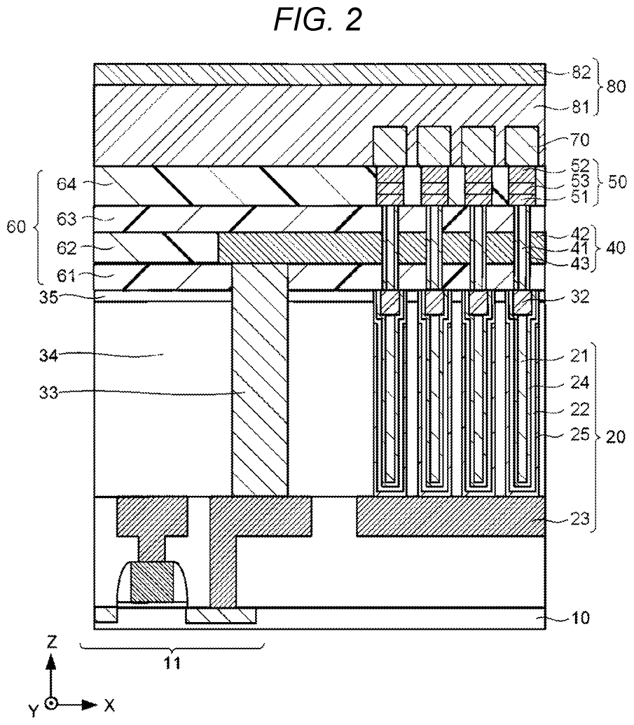

FIG. 2 is a schematic cross-sectional view illustrating a structure example of the semiconductor storage device and illustrates a portion of a Y-Z cross section of the memory cell array which includes a Y axis and a Z axis orthogonal to the Y axis.

The semiconductor storage device illustrated in FIG. 2 includes a semiconductor substrate 10, a circuit 11, an electric conductor 21, an insulating film 22, a conductor 23, an electric conductor 24, an electric conductor 25, a conductive oxide layer 32, a conductor 33, an insulating layer 34, an insulating layer 35, an oxide semiconductor layer 41, a conductive layer 42, an insulating layer 43, an insulating layer 45, a conductor 50, an insulating layer 60, a conductive layer 70, and an insulating layer 80.

The circuit 11 configures, for example, a peripheral circuit of a sense amplifier or the like. The circuit 11 includes, for example, a field effect transistor such as a P channel-type field effect transistor (Pch-FET) and an N channel-type field effect transistor (Nch-FET). The field effect transistor of the circuit 11 can be formed, for example, by using the semiconductor substrate 10 such as a single crystal silicon substrate, and the Pch-FET and the Nch-FET includes a channel region, a source region, and a drain region in the semiconductor substrate 10. In addition, the semiconductor substrate 10 may include a P-type conductivity type. Also, FIG. 2 illustrates a field effect transistor of the circuit 11, for convenience.

The electric conductor 21, the insulating film 22, the electric conductor 24, and the electric conductor 25 form a capacitor 20. The capacitor 20 is the memory capacitor MCP of the memory cell MC. FIG. 2 illustrates four capacitors 20, but the number of capacitors 20 is not limited to four.

The capacitor 20 may be a three-dimensional capacitor such as a so-called pillar-type capacitor or a cylinder-type capacitor. The electric conductor 21 has a function as a first electrode of the memory capacitor MCP. The insulating film 22 has a function as a dielectric layer of the memory capacitor MCP. The conductor 23 has a function as a second electrode of the memory capacitor MCP. The electric conductor 24 is provided between the electric conductor 21 and the insulating film 22. The electric conductor 25 is provided between the insulating film 22 and the insulating layer 34 and between the insulating film 22 and the conductor 23.

The electric conductor 21 includes, for example, a material such as amorphous silicon. The insulating film 22 includes a material such as hafnium oxide. The conductor 23, the electric conductor 24, and the electric conductor 25 include, for example, materials such as tungsten and titanium nitride.

The conductive oxide layer 32 is provided on the electric conductor 21. The conductive oxide layer 32 includes, for example, metal oxide such as indium-tin-oxide (ITO).

The conductor 33 is electrically connected to the circuit 11. The conductor 33 has a function as a pillar. The conductor 33 includes, for example, copper.

The insulating layer 34 is provided, for example, between the plurality of capacitors 20. The insulating layer 34 includes, for example, silicon and oxygen.

The insulating layer 35 is provided on the insulating layer 34. The insulating layer 35 includes, for example, silicon and nitrogen.

The oxide semiconductor layer 41, the conductive layer 42, and the insulating layer 43 form a field effect transistor 40. The field effect transistor 40 is the memory transistor MTR of the memory cell MC. The field effect transistor 40 is provided above the capacitor 20.

The oxide semiconductor layer 41 is a columnar-shaped body extending, for example, in a Z axis direction. The oxide semiconductor layer 41 forms a channel of the field effect transistor 40. The oxide semiconductor layer 41 includes, for example, indium (In). The oxide semiconductor layer 41 includes, for example, indium oxide and gallium oxide, indium oxide and zinc oxide, or indium oxide and tin oxide. For example, the oxide semiconductor layer 41 includes oxide including indium, gallium and zinc (indium-gallium-zinc-oxide), so-called IGZO (InGaZnO).

One end of the oxide semiconductor layer 41 in the Z axis direction is connected to a conductive layer 52 via a conductive oxide layer 51 and functions as one of a source or a drain of the field effect transistor 40, and the other end is connected to the conductive oxide layer 32 and functions as the other of the source or the drain of the field effect transistor 40. At this time, the conductive oxide layer 32 is provided between the electric conductor 21 of the capacitor 20 and the oxide semiconductor layer 41 of the field effect transistor 40 and functions as the other of the source electrode or the drain electrode of the field effect transistor 40. The conductive oxide layer 32 includes metal oxide similarly to the oxide semiconductor layer 41 of the field effect transistor 40 and thus can reduce connection resistance between the field effect transistor 40 and the conductive oxide layer 32.

The conductive layer 42 extends in a Y axis direction. The conductive layer 42 overlaps with the oxide semiconductor layer 41, with the insulating layer 43 interposed therebetween in the X-Y plane. The conductive layer 42 forms a gate electrode of the field effect transistor 40 and forms the word line WL as wiring. The conductive layer 42 includes, for example, metal, a metal compound, or a semiconductor. The conductive layer 42 includes at least one material selected from the group configured with tungsten (W), titanium (Ti), titanium nitride (TiN), molybdenum (Mo), cobalt (Co), and ruthenium (Ru). The conductive layer 42 is connected to the conductor 33.

In the X-Y plane, the insulating layer 43 is provided between the oxide semiconductor layer 41 and the conductive layer 42. The insulating layer 43 forms a gate insulating film of the field effect transistor 40. The insulating layer 43 includes, for example, silicon and oxygen or nitrogen.

The field effect transistor 40 is a so-called surrounding gate transistor (SGT) that is disposed so that a gate electrode surrounds a channel. The area of the semiconductor storage device can be reduced by the SGT.

The field effect transistor including a channel layer including an oxide semiconductor has an off-leakage current lower than a field effect transistor provided on the semiconductor substrate 10. As a result, for example, data stored in the memory cell MC can be stored for a long period of time, so the number of refresh operations can be reduced. Moreover, a field effect transistor including a channel layer including an oxide semiconductor can be formed by a low-temperature process and can prevent application of thermal stress to the capacitor 20.

The conductor 50 includes the conductive oxide layer 51, the conductive layer 52, and a conductive layer 53. The conductor 50 is electrically connected to the sense amplifier in the circuit 11 via the bit line BL. The conductor 50 has a function, for example, as a conductive pad for connecting the field effect transistor 40 and the bit line BL.

The conductive oxide layer 51 is a conductive layer including conductive oxide. The conductive oxide layer 51 is in contact with the oxide semiconductor layer 41 of the field effect transistor 40 and functions as one of the source electrode or the drain electrode of the field effect transistor 40. The conductive oxide layer 51 includes, for example, metal oxide such as indium-tin-oxide (ITO). The conductive oxide layer 51 includes metal oxide similarly to the oxide semiconductor layer 41 and thus can reduce connection resistance between the field effect transistor 40 and the conductive oxide layer 51.

The conductive layer 52 is provided on at least a portion of the conductive oxide layer 51. The conductive layer 52 forms an electrode electrically connected to the bit line BL (not illustrated). The conductive layer 52 includes a metal element. The conductive layer 52 includes, for example, a material such as tungsten or titanium nitride.

The conductive layer 52 is in contact with the conductive oxide layer 51 above the field effect transistor 40 and is connected to the oxide semiconductor layer 41 of the field effect transistor 40 via the conductive oxide layer 51. The conductive oxide layer 51 functions as one of the source electrode or the drain electrode of the field effect transistor 40.

The conductive layer 53 is provided between the conductive oxide layer 51 and the conductive layer 52. The conductive layer 53 is, for example, a metal compound layer and includes, for example, titanium and nitrogen. By forming the conductive layer 53, diffusion of oxygen from the conductive oxide layer 51 to the conductive layer 52 can be prevented.

The insulating layer 60 includes an insulating layer 61, an insulating layer 62, an insulating layer 63, and an insulating layer 64.

The insulating layer 61 is provided on the insulating layer 35. The insulating layer 62 is provided on the insulating layer 61. The insulating layer 63 is provided on the insulating layer 62. The insulating layer 64 is provided on the insulating layer 63. The insulating layers 61 to 64 form interlayer insulating films. The insulating layer 61, the insulating layer 62, the insulating layer 63, and the insulating layer 64 include, for example, silicon and oxygen.

The conductive layer 70 is provided on the conductor 50 and is connected to the conductor 50. The conductive layer 70 forms the bit lines BL as wiring.

The insulating layer 80 includes an insulating layer 81 and an insulating layer 82. The insulating layer 80 forms, for example, an interlayer insulating film.

The insulating layer 81 is provided on the insulating layer 64. The insulating layer 81 includes, for example, silicon and oxygen.

The insulating layer 82 is provided on the insulating layer 81. The insulating layer 82 includes, for example, silicon and nitrogen.

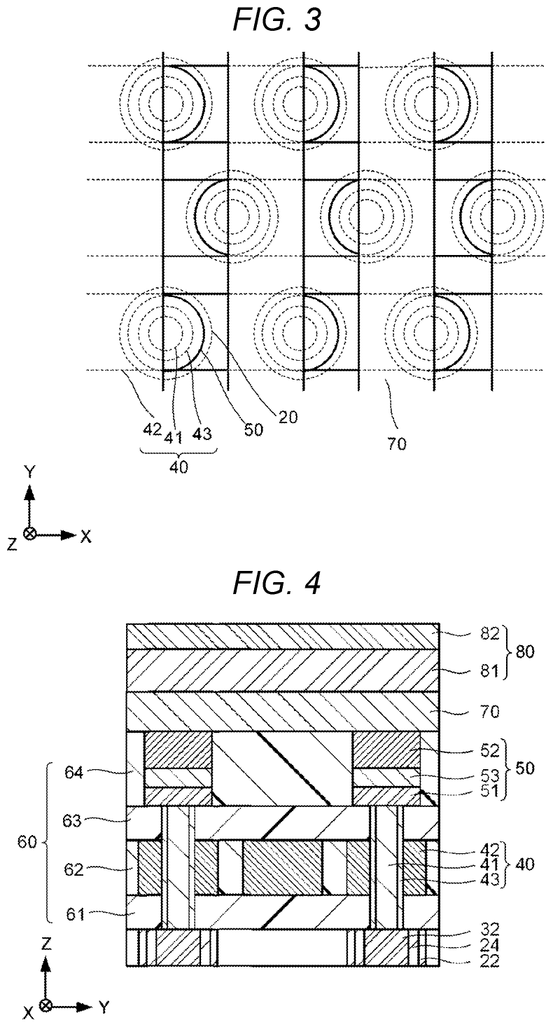

FIG. 3 is a schematic plan view illustrating the structure example of the memory cell array. FIG. 3 illustrates an X axis of the memory cell array, a Y axis of the memory cell array, and a Z axis of the memory cell array. The X axis, the Y axis, and the Z axis are orthogonal to each other. In addition, FIG. 3 illustrates the oxide semiconductor layer 41, the conductive layer 42, the insulating layer 43, the conductor 50, the capacitor 20, and the conductive layer 70, and illustration of other components is omitted for convenience.

The plurality of conductive layers 42 (the word lines WL) are located in parallel to each other. The conductive layers 42 each overlap with the plurality of memory cells MC in the X axis direction.

The plurality of conductive layers 70 (the bit lines BL) are located in parallel to each other. The conductive layers 70 each overlap with the plurality of memory cells MC in the Y axis direction.

The plurality of memory cells MC are located in a staggered manner in the X-Y plane as illustrated in FIG. 3. The memory cells MC connected to one of the plurality of word lines WL are deviated in the X axis direction with respect to the memory cells MC connected to the adjacent word lines WL. As a result, the degree of integration of the memory cells MC can be increased. In addition, the number of the memory cells MC is not particularly limited.

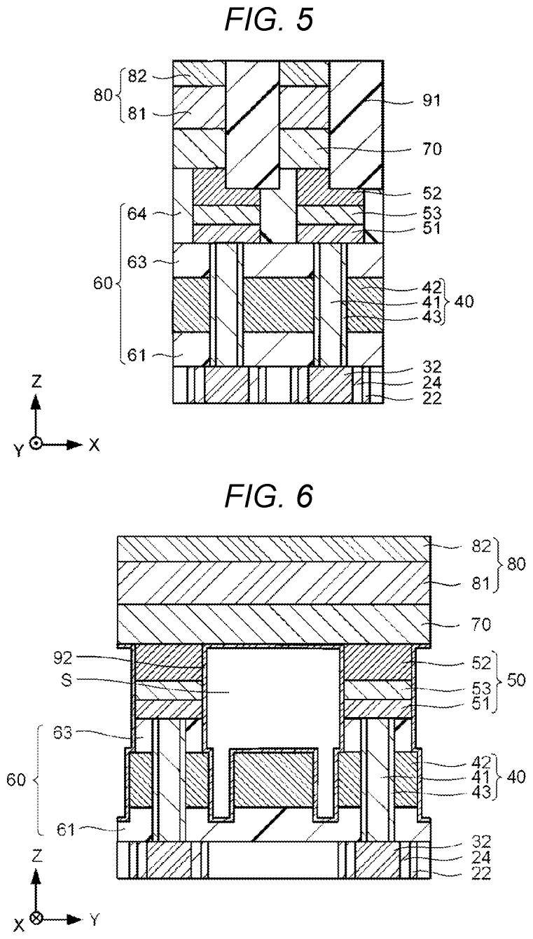

FIGS. 4 and 5 are schematic cross-sectional views illustrating the structure example of the memory cell array. FIG. 4 is a schematic cross-sectional view including the Y axis and the Z axis of the memory cell array illustrated in FIG. 3. FIG. 5 is a schematic cross-sectional view including the X axis and the Z axis of the memory cell array illustrated in FIG. 3.

In case of the memory cell array illustrated in FIGS. 4 and 5, since interlayer insulating films such as the insulating layers 61 to 64 are present in at least one of a portion between the plurality of conductive layers 42 (the word lines WL), a portion between the plurality of conductors 50, a portion between the conductive layer 42 (the word line WL) and the conductive layer 70 (the bit line BL), and thus a parasitic capacitance is great, the great parasitic capacitance causes operation malfunction of the memory cells MC to deteriorate the reliability of the semiconductor storage device. The parasitic capacitance becomes larger as the degree of integration of the memory cells MC is increased.

In order to reduce the parasitic capacitance, for example, it is considered to reduce the area of the conductor 50 and the wiring width of the conductive layer 70 (the bit line BL). However, due to such reduction, the contact resistance between the conductor 50 and the conductive layer 70 increases. Also, the positional deviation between the conductive layer 70 and the position of the conductor 50 causes the connection malfunction of the conductor 50 and the conductive layer 70. Further, signal interference (crosstalk) may occur between the plurality of conductive layers 42 (the word lines WL) or between the plurality of conductive layers 70 (the bit lines BL).

For this, one of the memory cell arrays of the semiconductor storage device according to the embodiment includes gaps formed by removing a portion of the interlayer insulating films. This achieves the prevent of the deterioration of the reliability of the semiconductor storage device.

Also, one of the memory cell arrays of the semiconductor storage device according to the embodiment shares the conductor 50 between the plurality of memory cells MC. Therefore, this achieves the prevention of the deterioration of the reliability of the semiconductor storage device.

A specific structure example of the memory cell array of the semiconductor storage device according to the embodiment is described below.

### First Structure Example of Memory Cell Array

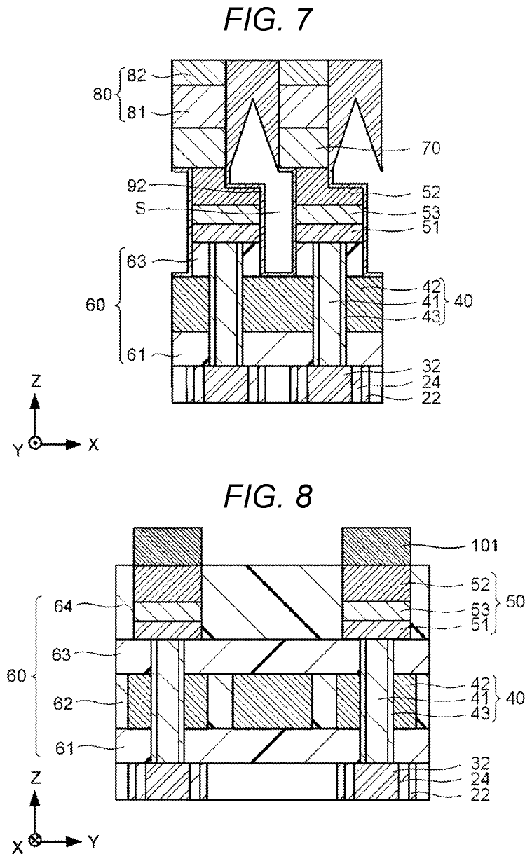

FIGS. 6 and 7 are schematic cross-sectional views illustrating a first structure example of the memory cell array. FIG. 6 is a schematic cross-sectional view illustrating the Y axis and the Z axis of the memory cell array. FIG. 7 is a schematic cross-sectional view including the X axis and the Z axis of the memory cell array illustrated in FIG. 3. In the following, portions different from FIGS. 4 and 5 are described, and the description with respect to FIGS. 4 and 5 can be appropriately used for the other portions.

The memory cell array illustrated in FIGS. 6 and 7 further includes a gap S and an insulating film 92 that are provided in at least a portion of a portion where the insulating layers 60 illustrated in FIGS. 4 and 5 are formed.

The gap S is provided, for example, in at least one of a portion between the plurality of conductive layers 42 (the word lines WL), a portion between the plurality of conductors 50, and a portion between the conductive layer 42 (the word line WL) and the conductive layer 70 (the bit line BL). FIGS. 6 and 7 illustrate the gap S extending between the plurality of conductive layers 42 (the word lines WL), between the plurality of conductors 50, and between the conductive layer 42 (the word line WL) and the conductive layer 70 (the bit line BL). The gap S may be filled, for example, with the air.

The insulating films 92 are provided between each of the conductive layer 42, the conductive oxide layer 51, the conductive layer 52, and the conductive layer 53 and the gap S to cover the front surfaces in contact with the gap S in each of the conductive layer 42, the conductive oxide layer 51, the conductive layer 52, and the conductive layer 53. The insulating film 92, for example, include silicon or aluminum and oxygen or nitrogen. The insulating film 92 has, for example, a function as a protective film. With the insulating film 92, for example, oxidation of each of the conductive layer 42, the conductive oxide layer 51, the conductive layer 52, and the conductive layer 53 can be prevented. The insulating film 92 may be formed with a plurality of insulating films.

As illustrated in FIGS. 6 and 7, the insulating film 92 is provided between each of the conductive layer 70, the insulating layer 81, and the insulating layer 82 and the gap S to cover the front surface in contact with the gap S in each of the conductive layer 70, the insulating layer 81, and the insulating layer 82. As a result, for example, the oxidation of the conductive layer 70 can be prevented. The embodiment is not limited to this, and the insulating film 92 may cover the front surface, for example, in contact with at least one gap S of the conductive layer 42, the conductive oxide layer 51, the conductive layer 52, the conductive layer 53, the conductive layer 70, the insulating layer 81, and the insulating layer 82.

In the first structure example, by forming the gap S, at least one parasitic capacitance between the plurality of conductive layers 42 (the word lines WL), between the plurality of conductors 50, or between the conductive layer 42 (the word line WL) and the conductive layer 70 (the bit line BL) can be reduced. Therefore, the deterioration of the reliability of the semiconductor storage device can be prevented.

### Manufacturing Method Example of First Structure Example

A first manufacturing method example of the first structure example is described with reference to FIGS. 8 to 27. FIGS. 8 to 27 are schematic cross-sectional views illustrating the first manufacturing method example of the first structure example. FIGS. 8, 10, 12, 14, 16, 18, 20, 22, 24, and 26 each are schematic cross-sectional views including the Y axis and the Z axis. FIGS. 9, 11, 13, 15, 17, 19, 21, 23, 25, and 27 each are schematic cross-sectional views including the X axis and the Z axis. Also, here, the manufacturing step from the formation of the insulating layer 64 to the formation of the insulating film 92 is described.

As illustrated in FIGS. 8 and 9, the field effect transistor 40, the insulating layer 60, and the conductor 50 each are formed. For example, the conductor 50 can be formed by sequentially forming the conductive oxide layer 51, the conductive layer 53, and the conductive layer 52 by sputtering or atomic layer deposition (ALD), forming a mask layer 101 for example, by using a photolithography technique, on the conductive layer 52, and by partially removing exposure portions to the conductive oxide layer 51, the conductive layer 53, and the conductive layer 52 by etching such as dry etching or wet etching using the corresponding mask layer 101. The insulating layer 60 can be formed by using CVD such as low pressure chemical vapor deposition (LP-CVD) or plasma CVD (PE-CVD), or a coating method.

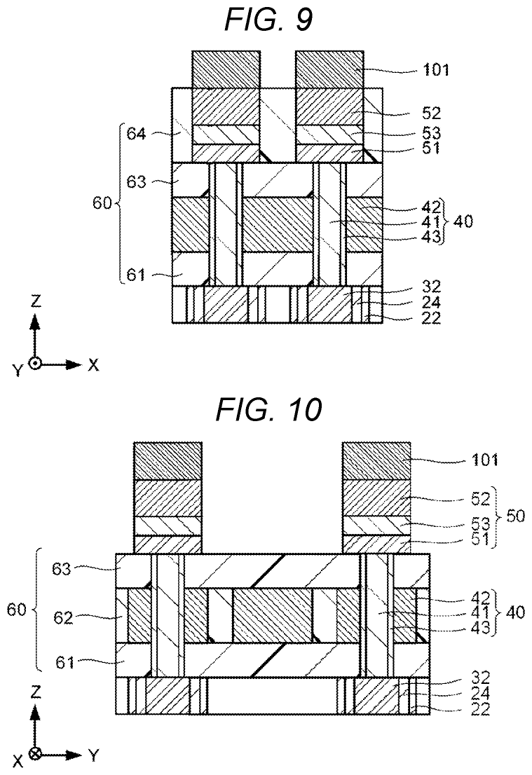

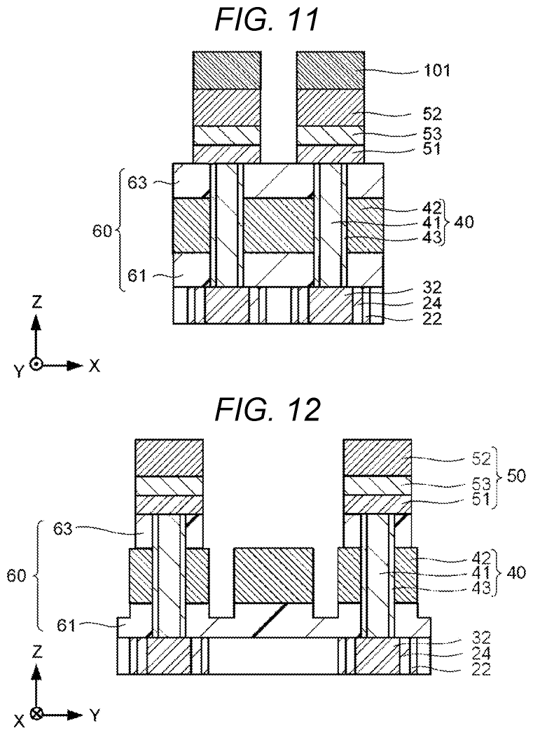

Next, as illustrated in FIGS. 10 and 11, a portion of the insulating layer 63 is exposed by etching with the mask layer 101 and removing the exposure portion of the insulating layer 64. Examples of the etching include dry etching and wet etching.

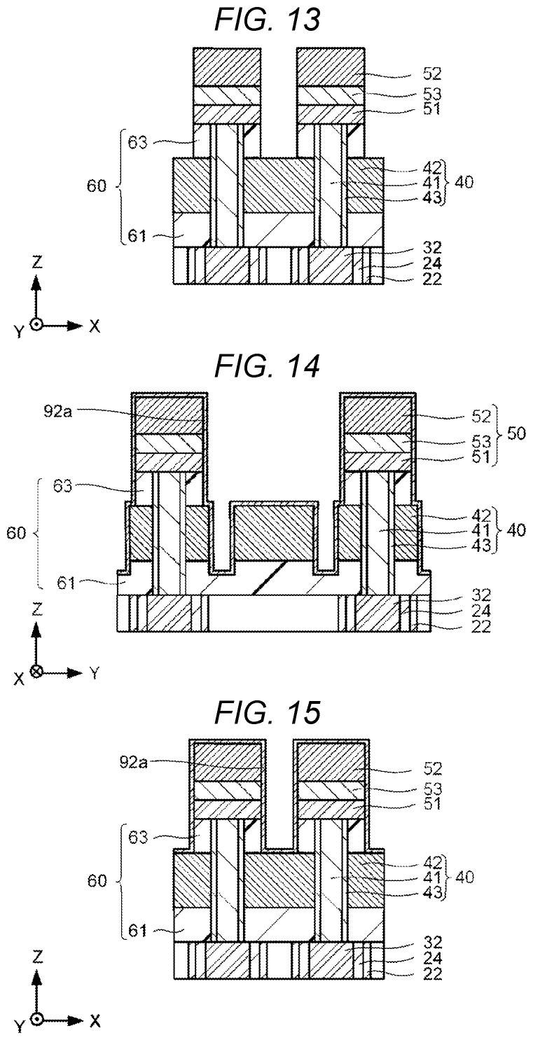

Next, as illustrated in FIGS. 12 and 13, a portion of each of the insulating layer 61 and the insulating layer 63 is removed in the thickness direction (Z axis direction), and the mask layer 101 is removed. The insulating layer 61 and the insulating layer 63 may be partially removed, for example, reactive ion etching (RIE). The mask layer 101 may be removed, for example, by reactive ion etching, dry etching, or wet etching. In addition, by adjusting etching time or the like, the insulating layer 62 and the insulating layer 63 may be partially removed, for example, without partially removing the insulating layer 61.

Next, as illustrated in FIGS. 14 and 15, an insulating film 92a that covers the front surface of each of the conductive layer 42, the conductive oxide layer 51, the conductive layer 52, and the conductive layer 53 is formed. The insulating film 92a includes, for example, silicon and oxygen. The insulating film 92a may be formed, for example, by using CVD and ALD.

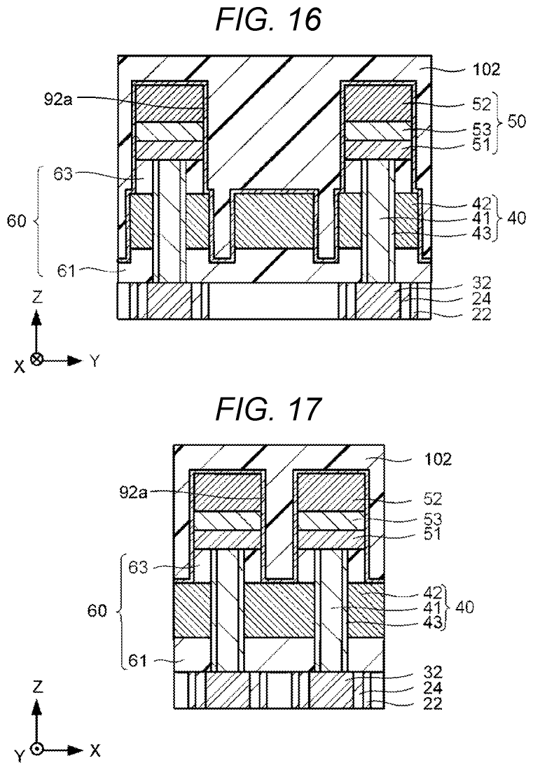

Next, as illustrated in FIGS. 16 and 17, a sacrifice layer 102 is formed on the front surface of the insulating film 92a. The sacrifice layer 102 is formed by forming the gap S. The sacrifice layer 102 includes, for example, amorphous silicon or silicon nitride. The sacrifice layer 102 may be formed, for example, by using sputtering, ALD, or CVD.

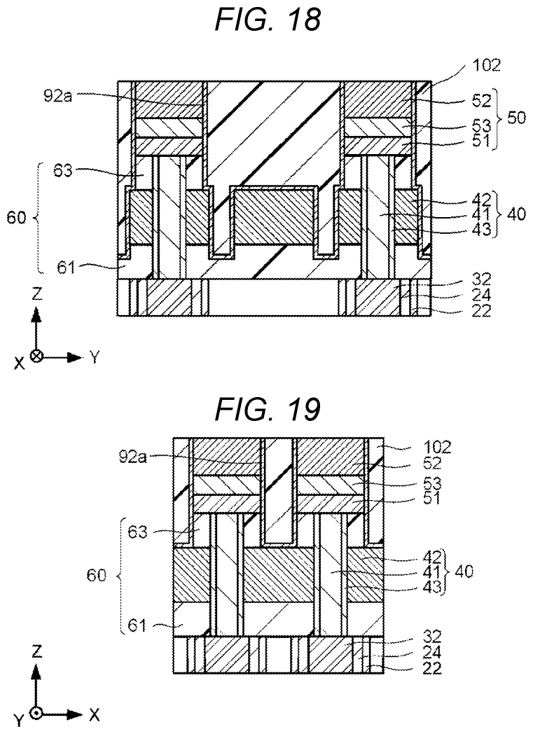

Next, as illustrated in FIGS. 18 and 19, a portion of the sacrifice layer 102 is removed in the thickness direction (Z axis direction) to expose the upper surface of the conductive layer 52. The sacrifice layer 102 may be partially removed, for example, by RIE.

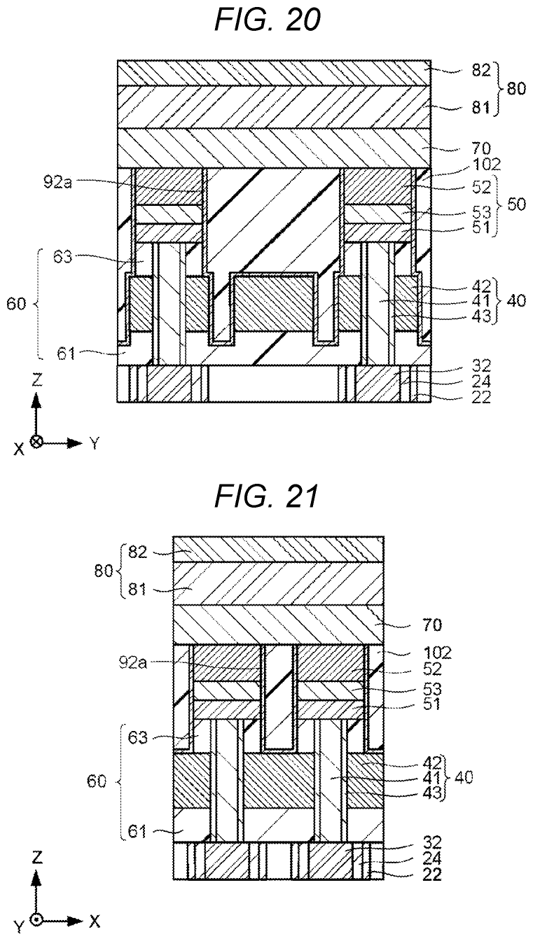

Next, as illustrated in FIGS. 20 and 21, the conductive layer 70 is formed on the conductive layer 52, the insulating layer 81 is formed on the conductive layer 70, and the insulating layer 82 is formed on the insulating layer 81. The conductive layer 70 may be formed, for example, by using sputtering or ALD. The insulating layer 81 and the insulating layer 82 may be formed, for example, by using CVD.

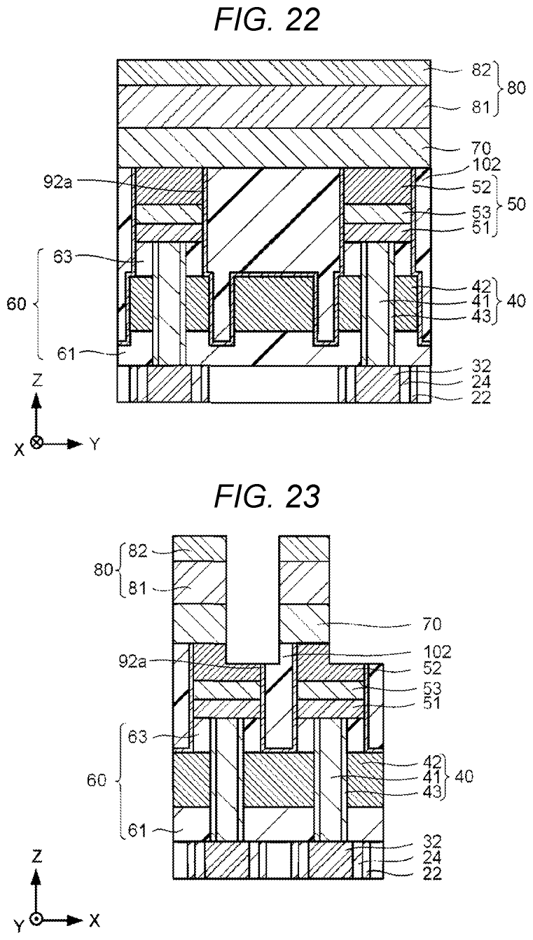

Next, as illustrated in FIGS. 22 and 23, the stacked layers of the conductive layer 70, the insulating layer 81, and the insulating layer 82 is partially removed in the thickness direction (Z axis direction), and a portion of the conductive layer 52 is removed. At this point, a portion in contact with the conductive layer 52 of the sacrifice layer 102 may also be removed. The conductive layer 70, the insulating layer 81, the insulating layer 82, and the conductive layer 52 may be partially removed, for example, by RIE.

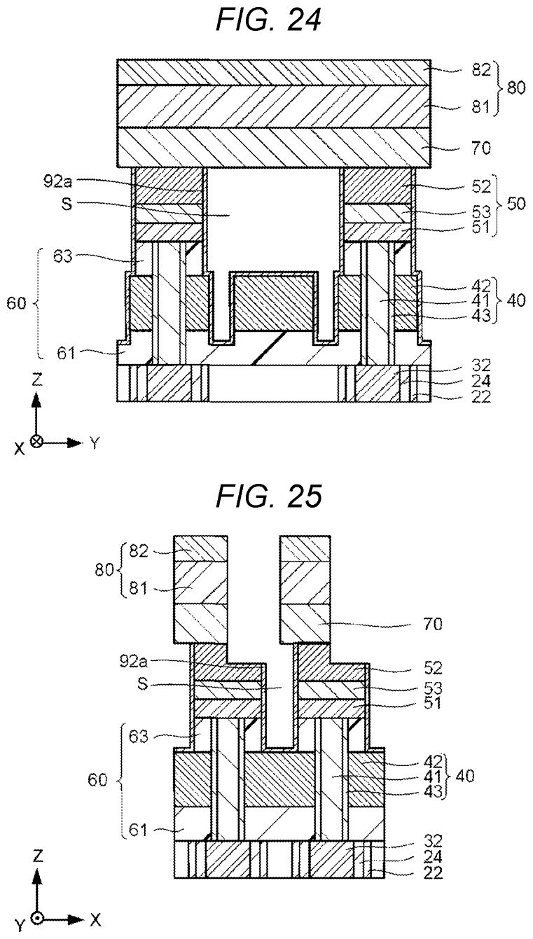

Next, as illustrated in FIGS. 24 and 25, the gap S is formed by removing the sacrifice layer 102. The sacrifice layer 102 may be removed by wet etching, for example, with cholic acid (TMY) or phosphoric acid (H₃PO₄).s

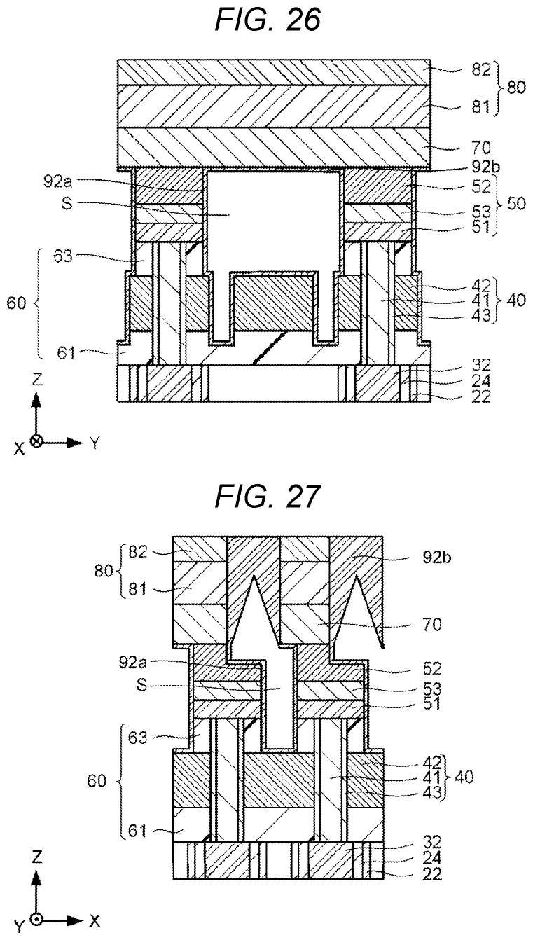

Next, as illustrated in FIGS. 26 and 27, an insulating film 92b that cover the front surface in contact with the gap S of each of the conductive layer 70, the insulating layer 81, and the insulating layer 82 is formed. The insulating film 92b includes, for example, silicon and oxygen. The insulating film 92b may be formed, for example, by using CVD and ALD. The insulating film 92b preferably has poorer coverage (step coverage) than the insulating film 92a. Therefore, the gap S may be closed by the insulating film 92a. The insulating film 92a and the insulating film 92b form the insulating film 92 illustrated in FIGS. 6 and 7. For the formation method of the other components, known methods may be used. The above is the description of the first manufacturing method example of the first structure example.

As described above, in the first manufacturing method example, the gap S can be easily formed by using the sacrifice layer 102.

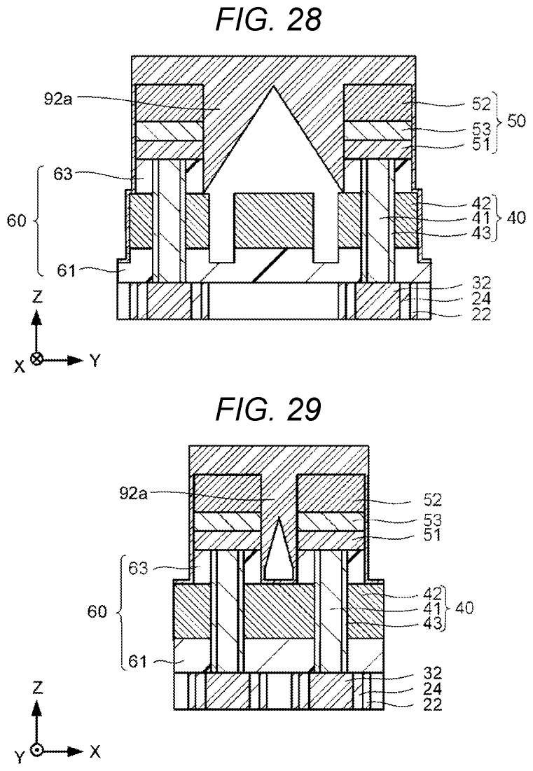

The manufacturing method example of the first structure example is not limited to the first manufacturing method example. A second manufacturing method example of the first structure example is described with reference to FIGS. 28 to 33. FIGS. 28 to 33 are schematic cross-sectional views illustrating the second manufacturing method example of the first structure example. FIGS. 28, 30, 32, and 34 each are schematic cross-sectional views including the Y axis and the Z axis. FIGS. 29, 31, 33, and 35 are schematic cross-sectional views including the X axis and the Z axis. In addition, here, portions different from the first manufacturing method example are described, and the description of the first manufacturing method example can be appropriately used for the other portions.

After the mask layer 101 is removed via the steps illustrated in FIGS. 8 to 13, the insulating film 92a that covers the front surface of each of the conductive layer 42, the conductive oxide layer 51, the conductive layer 52, and the conductive layer 53 is formed as illustrated in FIGS. 28 and 29. In FIGS. 28 and 29, the insulating film 92a is formed thick so as to close the recess portion between the plurality of conductors 50. The insulating film 92a includes, for example, silicon and oxygen. The insulating film 92a may be formed, for example, by using CVD or ALD.

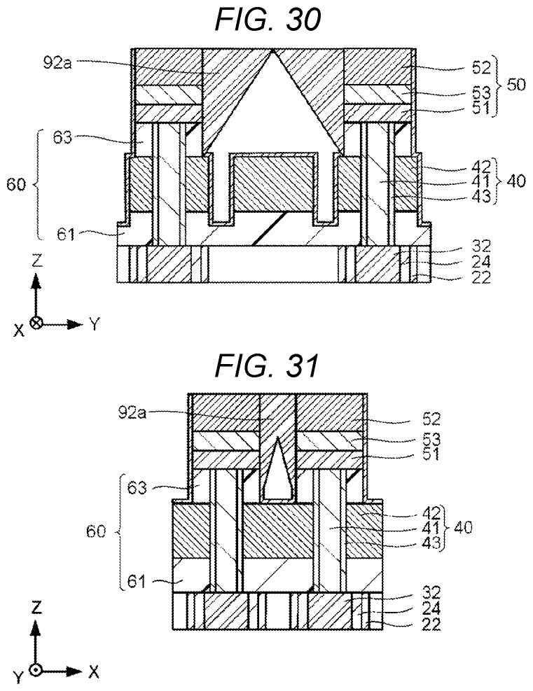

Next, as illustrated in FIGS. 30 and 31, a portion of the insulating film 92a is removed in the thickness direction (Z axis direction) to expose the upper surface of the conductive layer 52. The sacrifice layer 102 may be partially removed, for example, by RIE.

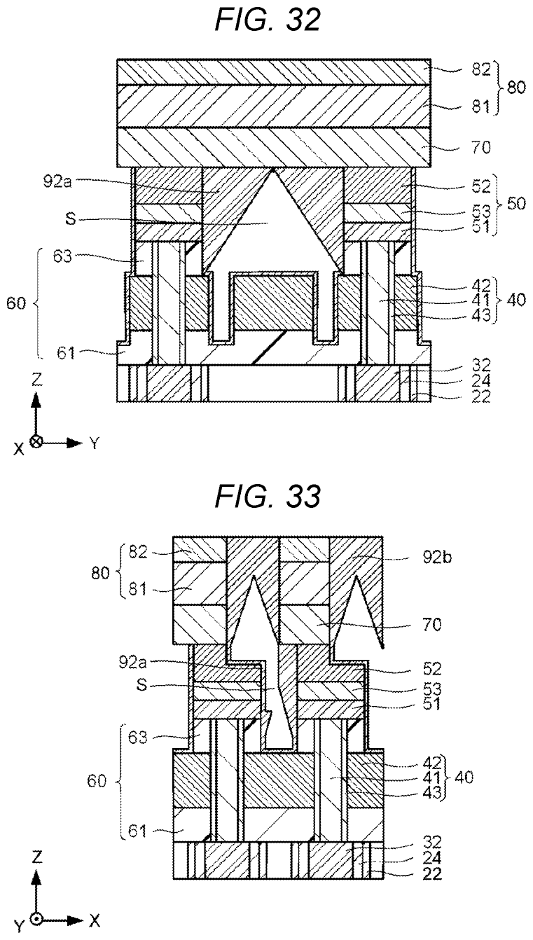

Thereafter, by steps similar to those in the first manufacturing method, the conductive layer 70, the insulating layer 81, the insulating layer 82, the insulating film 92b, and the gap S are formed as illustrated in FIGS. 32 and 33. For the formation method of the other components, known methods may be used. The above is the description of the second manufacturing method example of the first structure example.

In the second manufacturing method example, the gap S can be formed without using the sacrifice layer. As a result, the increase of the number of the manufacturing steps can be prevented.

### Modification Example of First Structure Example

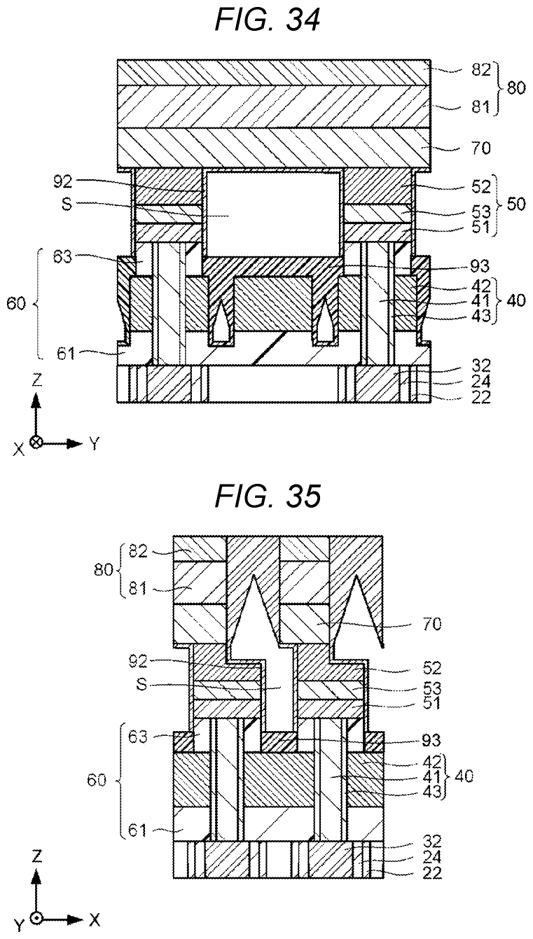

FIGS. 34 and 35 are schematic cross-sectional views illustrating a first modification example of the first structure example of the memory cell array. FIG. 34 is a schematic cross-sectional view including the Y axis and the Z axis. FIG. 35 is a schematic cross-sectional view including the X axis and the Z axis. The memory cell array illustrated in FIGS. 34 and 35 further includes an insulating film 93 in addition to the components illustrated in FIGS. 6 and 7. In the following, portions different from FIGS. 6 and 7 are described, and the description of FIGS. 6 and 7 may be appropriately used for the other portions.

The insulating film 93 covers the side surface of the conductive layer 42. The insulating film 93 has a function as a protective film of the conductive layer 42. The insulating film 93 includes silicon, and oxygen or nitrogen. The insulating film 93 may prevent, for example, the oxidation of the conductive layer 42.

The insulating film 92 is provided on the insulating film 93 and covers the front surface that is in contact with the gap S of each of the conductive oxide layer 51, the conductive layer 52, and the conductive layer 53.

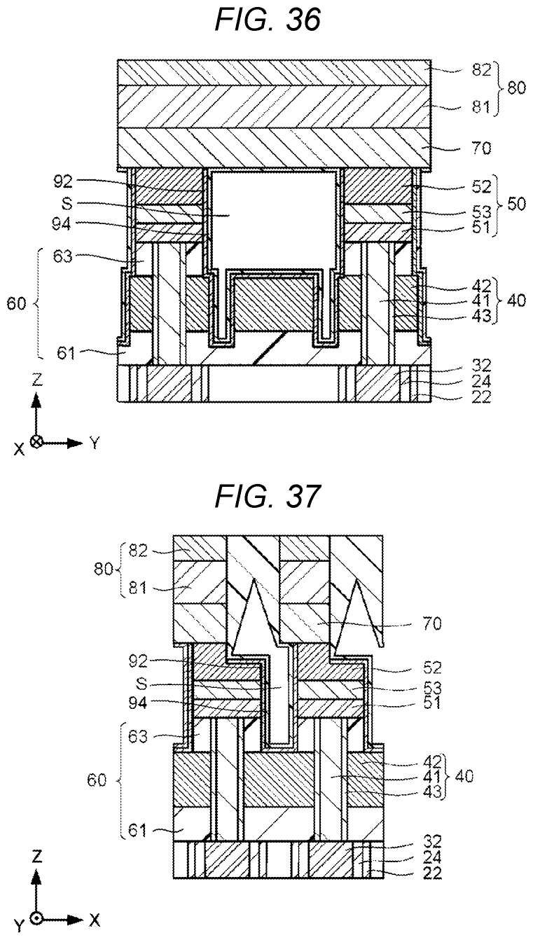

FIGS. 36 and 37 are schematic cross-sectional views illustrating a second modification example of the first structure example of the memory cell array. FIG. 36 is a schematic cross-sectional view including the Y axis and the Z axis. FIG. 37 is a schematic cross-sectional view including the X axis and the Z axis. The memory cell array illustrated in FIGS. 36 and 37 further includes an insulating film 94 in addition to the components illustrated in FIGS. 6 and 7. In the following, portions different from those in FIGS. 6 and 7 are described, and the description of FIGS. 6 and 7 can be appropriately used for the other portions.

The insulating film 94 is provided on the front surface of the insulating film 92. The insulating film 94 includes silicon and nitrogen.

The insulating film 92 is provided between the insulating film 92 and the gap S to cover the front surface in contact with the gap S of the conductive layer 42, the conductive oxide layer 51, the conductive layer 52, and the conductive layer 53. The insulating film 92 includes silicon and oxygen.

As illustrated above, the oxidation prevention effect can be increased by covering the front surface in contact with the gap S of each of the conductive layer 42, the conductive oxide layer 51, the conductive layer 52, and the conductive layer 53 with the plurality of insulating films.

### Second Structure Example of Memory Cell Array

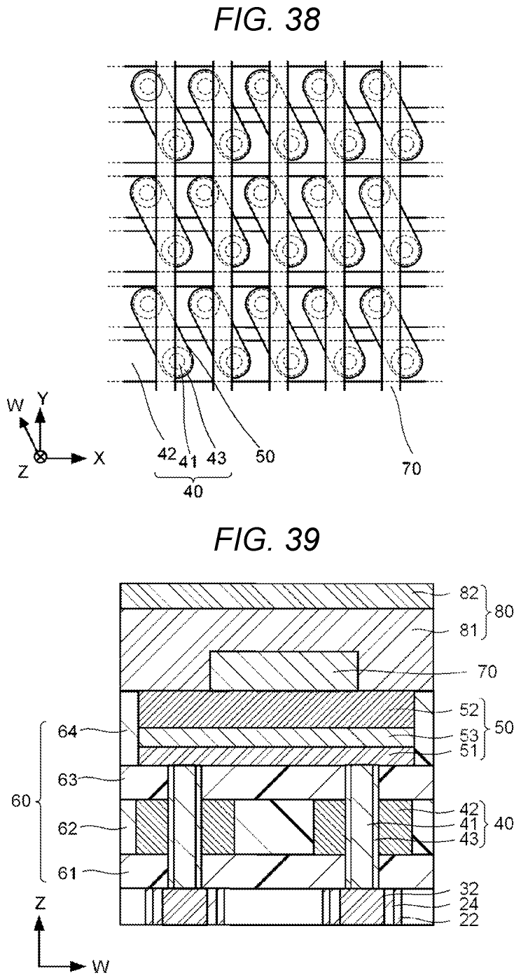

FIG. 38 is a schematic plan view illustrating a second structure example of the memory cell array and illustrates the X axis, the Y axis, the Z axis, and the W axis of the memory cell array. The W axis is any direction on the X-Y plane intersecting to each of the X axis, the Y axis, and the Z axis. FIG. 39 is a schematic cross-sectional view illustrating the second structure example of the memory cell array and is a schematic cross-sectional view including the Z axis and the W axis. In the following, portions different from those in FIGS. 3 to 5 are described, and the description of FIGS. 3 to 5 can be appropriately used for the other portions.

The memory cell array illustrated in FIGS. 38 and 39 has a structure in which the conductor 50 extends on the plurality of oxide semiconductor layers 41 along the W axis direction. It is preferable that the extending direction of the conductor 50 (W axis direction) has, for example, an angle of 45 degrees to 85 degrees with respect to the extending direction (X axis direction) of the conductive layer 42 (the word line WL). Therefore, the conductor 50 can extend to pass under the conductive layer 70 in the W axis direction. FIGS. 38 and 39 illustrate the structure in which the conductive oxide layer 51, the conductive layer 53, and the conductive layer 52 each extend above the plurality of oxide semiconductor layers 41 along the W axis direction, but the embodiment is not limited thereto. At least the conductive layer 52 may extend over the plurality of oxide semiconductor layers 41 along the W axis direction. In FIG. 38, the conductor 50 has an oval shape when viewed in the Z axis direction. By causing the conductor 50 to have an oval shape, for example, at the time of the operation of the semiconductor storage device, the electric field concentration to a portion of the conductor 50 can be prevented.

In the Y axis direction, the conductive layers 70 (the bit lines BL) extends to intersect to each of the conductor 50 and the plurality of conductive layers 42 (the word lines WL). FIGS. 38 and 39 illustrate a structure in which the conductive layers 70 overlap with a portion of the plurality of oxide semiconductor layers 41 in the Z axis direction, but the embodiment is not limited thereto. The conductive layers 70 may be provided on the conductor 50 without overlapping with a portion of each of the plurality of oxide semiconductor layers 41 in the Z axis direction.

In the second structure example, by forming the conductors 50 that pass under the conductive layers 70 (the bit lines BL) and extend on each of the plurality of field effect transistors 40 connected to the different conductive layers 42 (the word lines WL), for example, even if the area of the conductor 50 and the line width of the conductive layer 70 are small, a connection malfunction by the position deviation between the conductor 50 and the conductive layer 70 is prevented, and the parasitic capacitance between the wiring can be reduced. In addition, the contact area between the conductor 50 and the conductive layer 70 can be enlarged, and thus the connection resistance can be reduced. As a result, the deterioration of the reliability of the semiconductor storage device can be prevented.

### Manufacturing Method Example of Second Structure Example

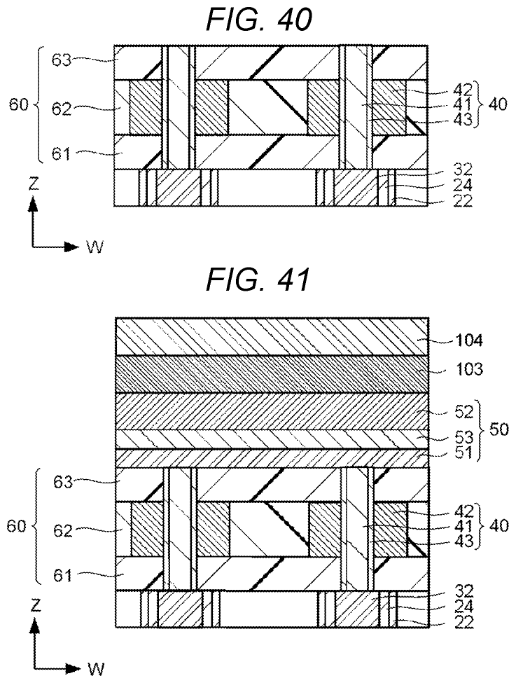

A first manufacturing method example of the second structure example is described with reference to FIGS. 40 to 43. FIGS. 40 to 43 are schematic cross-sectional views illustrating the manufacturing method example of the second structure example. FIGS. 40 to 43 each are schematic cross-sectional views including the W axis and the Z axis. In addition, here, the manufacturing step from the formation of the field effect transistor 40 to the formation of the conductor 50 is described.

As illustrated in FIG. 40, the field effect transistor 40, the insulating layer 61, the insulating layer 62, and the insulating layer 63 are formed respectively.

Next, as illustrated in FIG. 41, the conductive oxide layer 51, the conductive layer 53, the conductive layer 52, a mask layer 103, and a mask layer 104 are sequentially formed. The conductive oxide layer 51, the conductive layer 53, and the conductive layer 52 may be formed, for example, by using sputtering or ALD.

The mask layer 103 includes, for example, a metal element and has a function as a hard mask. The mask layer 103 may be formed, for example, by using sputtering or ALD.

The mask layer 104 includes, for example, a resin material such as polyethylene polyol (PEP). The mask layer 103 may be formed, for example, by using a coating method.

Next, as illustrated in FIG. 42, a portion of the conductive layer 52 is exposed by partially removing the mask layer 103 and the mask layer 104 in the thickness direction (Z axis direction). In order to process the conductor 50 and form a pattern in a desired shape, the mask layer 103 and the mask layer 104 are processed into a shape in accordance with the pattern. The mask layer 103 and the mask layer 104 may be partially removed, for example, by etching such as dry etching or wet etching.

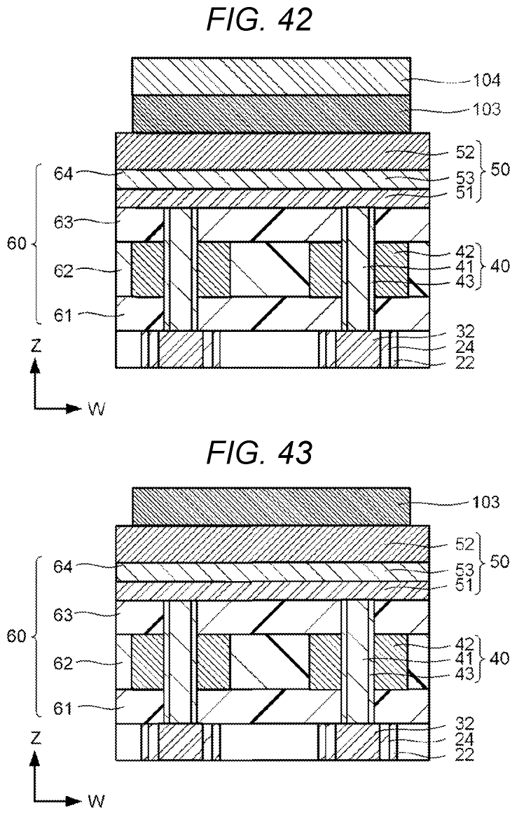

Next, as illustrated in FIG. 43, the mask layer 104 is removed. The mask layer 104 may be removed, for example, by asking. Thereafter, the conductive oxide layer 51, the conductive layer 53, and the conductive layer 52 are partially removed in the thickness direction (Z axis direction) by etching with the mask layer 103, to form the conductor 50. The conductive oxide layer 51, the conductive layer 53, and the conductive layer 52 may be partially removed, for example, by etching such as dry etching or wet etching. For the formation method of the other components, known methods may be used. The above is the description of the first manufacturing method example of the second structure example.

In the first manufacturing method example, the number of steps required for the formation of the hard mask may be reduced by processing the mask layer 103 and the mask layer 104 by etching once.

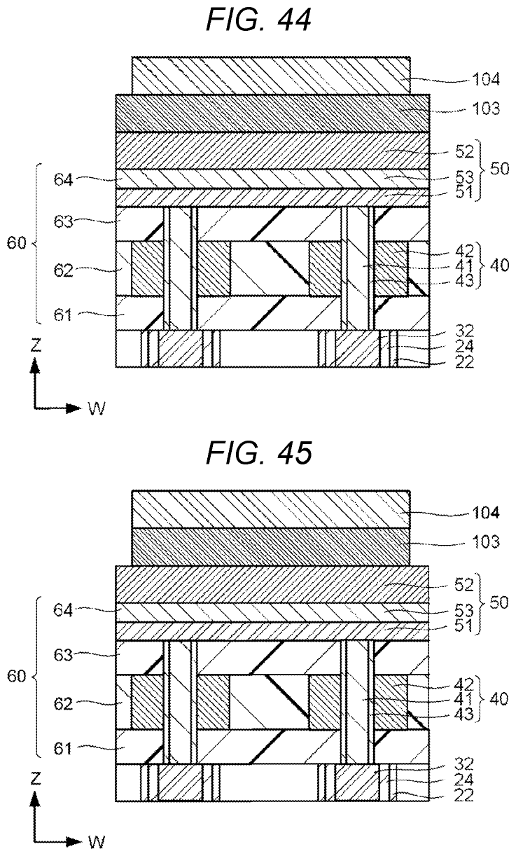

The manufacturing method example of the second structure example is not limited to the first manufacturing method example. A second manufacturing method example of the second structure example is described with reference to FIGS. 44 and 45. FIGS. 44 and 45 are schematic cross-sectional views illustrating the second manufacturing method example of the first structure example. FIGS. 44 and 45 each are schematic cross-sectional views including the W axis and the Z axis. Here, portions different from those in the first manufacturing method example are described, and the description of the first manufacturing method example may be appropriately used for the other portions.

After the conductive oxide layer 51, the conductive layer 53, the conductive layer 52, the mask layer 103, and the mask layer 104 are sequentially formed via the steps illustrated in FIGS. 40 and 41, a portion of the mask layer 103 is exposed by partially removing the mask layer 104 in the thickness direction (Z axis direction) as illustrated in FIG. 44. In order to form a pattern having a desired shape by processing the conductor 50, the mask layer 104 is processed in a shape in accordance with the pattern. The mask layer 104 may be partially removed, for example, by etching such as dry etching or wet etching.

Next, as illustrated in FIG. 45, the mask layer 103 is partially removed by etching with the mask layer 104. The mask layer 103 may be partially removed, for example, by etching such as dry etching or wet etching.

Thereafter, by the step similar to the first manufacturing method, the mask layer 104 is removed, the conductive oxide layer 51, the conductive layer 53, and the conductive layer 52 are partially removed in the thickness direction (Z axis direction) by etching with the mask layer 103, to form the conductor 50. For the formation method of the other components, known methods may be used. The above is the description of the second manufacturing method example of the second structure example.

In the second manufacturing method example, by processing the mask layer 103 and the mask layer 104 by etching a plurality of times, a hard mask having a desired shape can be easily formed.

### Modification Example of Second Structure Example

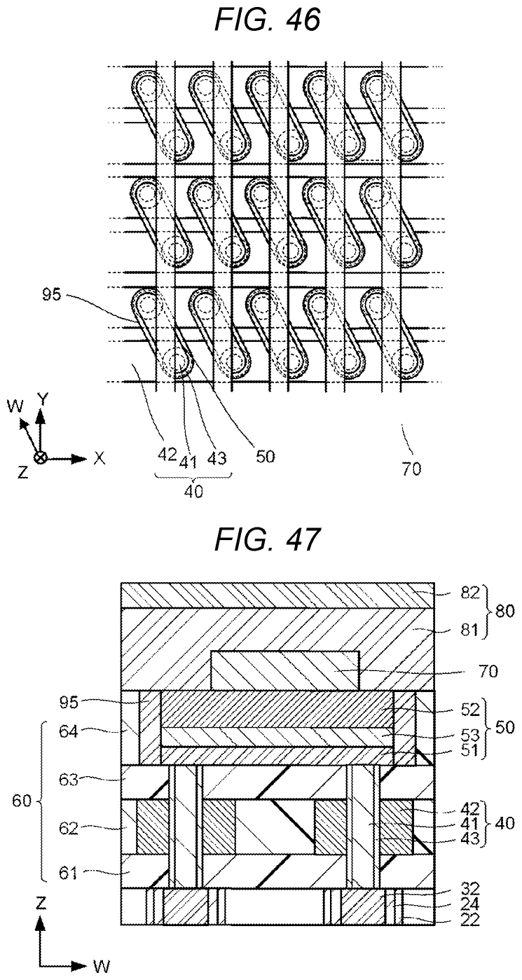

FIG. 46 is a schematic plan view illustrating a first modification example of the second structure example and illustrates the X axis, the Y axis, the Z axis, and the W axis of the memory cell array. FIG. 47 is a schematic cross-sectional view illustrating the first modification example of the second structure example and is a schematic cross-sectional view including the Z axis and the W axis. The memory cell array illustrated in FIGS. 46 and 47 further include an insulating film 95 in addition to the components illustrated in FIGS. 38 and 39. In the following, portions different from those in FIGS. 38 and 39 are described, and the description of FIGS. 38 and 39 can be appropriately used for the other portions.

The insulating film 95 covers the side surfaces of each of the conductive oxide layer 51, the conductive layer 52, and the conductive layer 53. The insulating film 95 includes silicon, oxygen, or nitrogen. The insulating film 95 may be a stacked layers of silicon oxide films and silicon nitride films. The insulating film 95 may be formed by low pressure plasma CVD (LP-CVD) or thermal CVD. After the insulating film 95 is formed to cover each of the conductive oxide layer 51, the conductive layer 52, and the conductive layer 53, and then is partially removed, for example, by chemical mechanical polishing (CMP) so that the conductive layer 52 is exposed.

By forming the insulating film 95, even if the area of the conductor 50 is reduced, the conductor 50 can be stably disposed. By narrowing the line width of the conductive layers 70 (the bit lines BL) together with reducing the area of the conductor 50 to increase the wiring interval, the parasitic capacitance between wiring can be reduced.

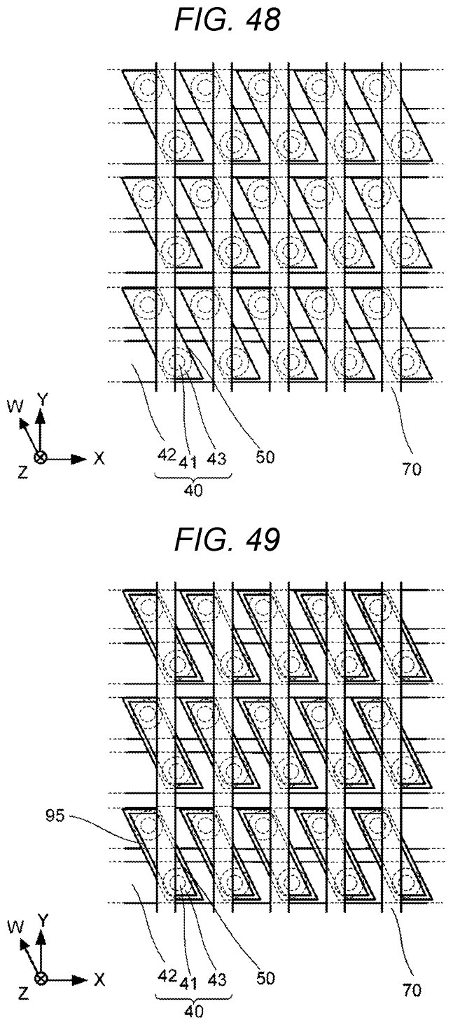

FIGS. 48 and 49 are schematic plan views illustrating the second modification example of the second structure example of the memory cell array and illustrate the X axis, the Y axis, the Z axis, and the W axis of the memory cell array. The memory cell array illustrated in FIG. 48 differs in the shape of the conductor 50 illustrated in FIGS. 38 and 39. In the following, portions different from those in FIGS. 38 and 39 are described, and the description of FIGS. 38 and 39 can be appropriately used for the other portions.

The conductor 50 has a polygonal shape such as a parallelogram when viewed from the Z axis direction. The conductor 50 having a polygonal shape can be formed, for example, by processing the mask layer 103 into a polygonal shape by the second manufacturing method example of the second structure example and partially removing the conductive oxide layer 51, the conductive layer 53, and the conductive layer 52 in the thickness direction (Z axis direction) by etching the processed mask layer 103.

The second modification example can be appropriately combined with the first modification example of the second structure example. For example, as illustrated in FIG. 49, the insulating film 95 that covers the side surface of each of the conductive oxide layer 51, the conductive layer 52, and the conductive layer 53 of the conductor 50 may be formed.

By processing the conductor 50 into a polygonal shape, for example, the area of the conductor 50 is increased, so that the contact resistance between the conductor 50 and the conductive layers 70 (the bit lines BL) can be reduced.

FIGS. 50 to 57 are schematic plan views illustrating a third modification example of the second structure example of the memory cell array and illustrate the X axis, the Y axis, the Z axis, and the W axis of the memory cell array.

The memory cell array illustrated in FIG. 50 differs in the shape of the conductor 50 illustrated in FIGS. 38 and 39. In the following, portions different from those in FIGS. 38 and 39 are described, and the description of FIGS. 38 and 39 can be appropriately used for the other portions.

The conductor 50 has a structure of extending on the three oxide semiconductor layers 41 along the W axis direction. The three oxide semiconductor layers 41 overlap with the conductive layers 42 (the word lines WL) different from each other. The conductor 50 extends to pass under the conductive layer 70 in the W axis direction. In FIG. 50, the conductor 50 overlaps with at least one of the oxide semiconductor layers 41 in the Z axis direction and has an oval shape when viewed in the Z axis direction.

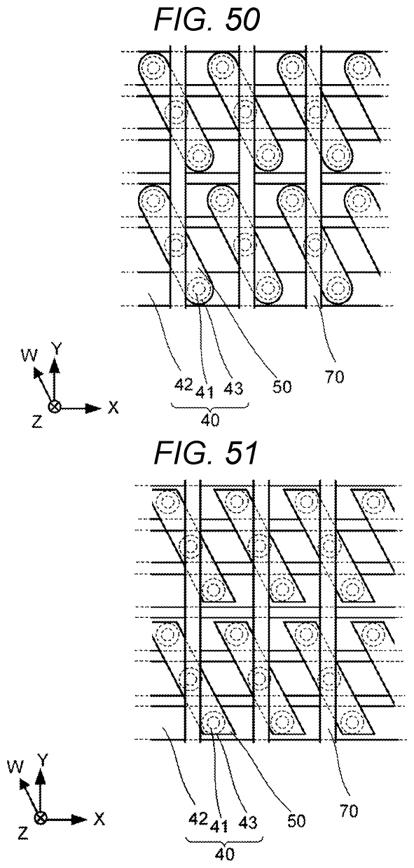

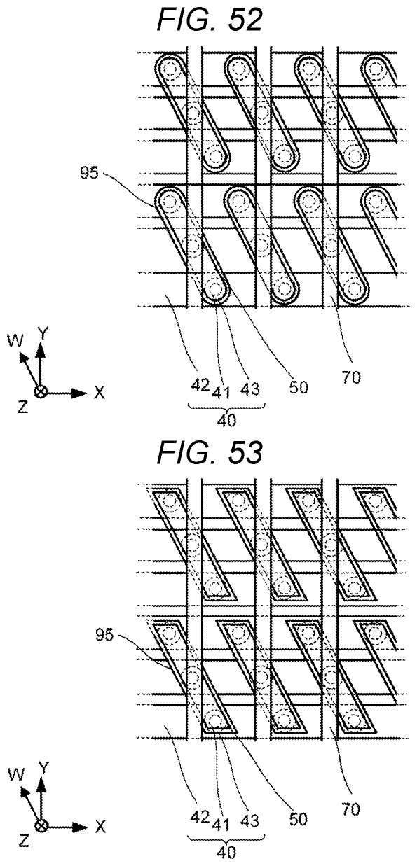

As illustrated in FIG. 51, similarly to the second modification example, the conductor 50 may have a polygonal shape such as a parallelogram when viewed in the Z axis direction. Also, as illustrated in FIGS. 52 and 53, similarly to the first modification example, the insulating film 95 that cover the side surface of each of the conductive oxide layer 51, the conductive layer 52, and the conductive layer 53 of the conductor 50 may be formed.

Further, as illustrated in FIG. 54, the conductor 50 may have a structure extending on the four oxide semiconductor layers 41 along the W axis direction. The four oxide semiconductor layers 41 overlaps with the conductive layers 42 (the word lines WL) different from each other. The conductor 50 extends to pass under the conductive layer 70 in the W axis direction. In FIG. 54, the conductor 50 has an oval shape when viewed in the Z axis direction.

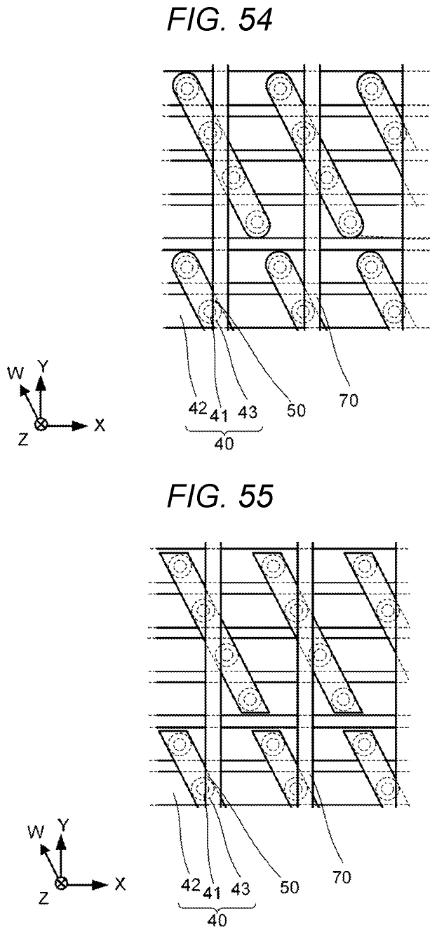

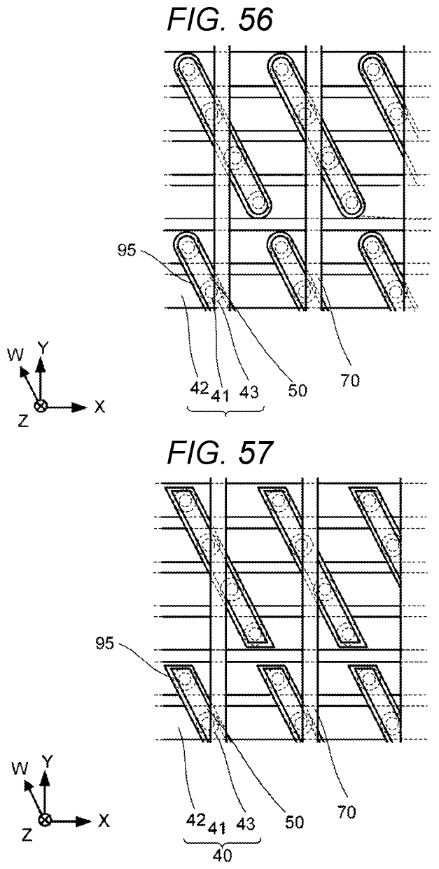

As illustrated in FIG. 55, similarly to the second modification example, the conductor 50 may have a polygonal shape such as a parallelogram when viewed in the Z axis direction. Also, as illustrated in FIGS. 56 and 57, similarly to the first modification example, the insulating film 95 that covers the side surface of each of the conductive oxide layer 51, the conductive layer 52, and the conductive layer 53 of the conductor 50 may be formed.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device comprising:
a first oxide semiconductor layer extending in a first direction;
a second oxide semiconductor layer extending in the first direction and being adjacent to the first oxide semiconductor layer in a second direction intersecting the first direction;
first wiring extending in a third direction intersecting the first direction and overlapping the first oxide semiconductor layer in the third direction;
second wiring extending in the third direction and overlapping the second oxide semiconductor layer in the third direction;
a first insulating film disposed between the first wiring and the first oxide semiconductor layer;
a second insulating film that disposed between the second wiring and the second oxide semiconductor layer;
a first conductor disposed on the first oxide semiconductor layer;
a second conductor disposed on the second oxide semiconductor layer; and
an insulating layer having a gap between the first conductor and the second conductor or between the first wiring and the second wiring.

2. The semiconductor storage device according to claim 1, further comprising:
a third conductor disposed between the first conductor and the second conductor; and
third wiring extending on the first conductor, on the second conductor, and on the third conductor,
wherein the gap extends between the first conductor and the second conductor, between the first wiring and the second wiring, and between the third conductor and the third wiring.

3. The semiconductor storage device according to claim 1, further comprising:
an insulating film disposed between each of the first wiring, the second wiring, the first conductor, and the second conductor, and the gap.

4. A semiconductor storage device comprising:
a first oxide semiconductor layer extending in a first direction;
a second oxide semiconductor layer extending in the first direction and being adjacent to the first oxide semiconductor layer in a second direction intersecting the first direction;
first wiring extending in a third direction intersecting each of the first direction and the second direction and overlapping with the first oxide semiconductor layer in the third direction;
second wiring extending in the third direction and overlapping with the second oxide semiconductor layer in the third direction;
a first insulating film disposed between the first wiring and the first oxide semiconductor layer;
a second insulating film disposed between the second wiring and the second oxide semiconductor layer;
a conductor extending on the first oxide semiconductor layer and on the second oxide semiconductor layer in the second direction;
third wiring disposed on the conductor and extending to intersect each of the first wiring, the second wiring, and the conductor in a fourth direction intersecting each of the first direction, the second direction, and the third direction.

5. The semiconductor storage device according to claim 4, further comprising:
an insulating film covering a side surface of the conductor.

6. The semiconductor storage device according to claim 1, wherein the semiconductor storage device includes a memory cell array.

7. The semiconductor storage device according to claim 1, wherein the first oxide semiconductor layer and the second oxide semiconductor layer includes indium, gallium and zinc.

8. The semiconductor storage device according to claim 1, wherein the first insulating film and the second insulating film includes silicon and at least one of nitrogen or oxygen.
